(19) United States
(12) Patent Application Publication
(10) Pub. No.: US 2026/0101801 A1
(43) Pub. Date: Apr. 9, 2026

(54) THERMAL DISTRIBUTION LAYERS IN STACKED SEMICONDUCTOR ARCHITECTURES

(71) Applicant: Micron Technology, Inc., Boise, ID (US)

(72) Inventor: William M. Brewer, Boise, ID (US)

(21) Appl. No.: 19/336,200

(22) Filed: Sep. 22, 2025

Related U.S. Application Data
(60) Provisional application No. 63/702,982, filed on Oct. 3, 2024.

(51) Int. Cl. H01L 23/00

(52) U.S. Cl. CPC H10W 72/90; H10W 99/00; H10W 72/951; H10W 80/312; H10W 80/327; H10W 90/792

(57) ABSTRACT

Methods, systems, and devices for thermal distribution layers in stacked semiconductor architectures are described. A semiconductor system may include a first semiconductor die with first circuitry and a first dielectric material, and a second semiconductor die with second circuitry and a second dielectric material. A third dielectric material, having a higher thermal conductivity than the first and second dielectric materials, may be positioned between the first and second semiconductor dies. The third dielectric material may be in contact with the surfaces of both the first and second semiconductor dies. Conductors may be formed through the third dielectric material and may couple the first circuitry with the second circuitry. The system may include additional contacts and coating materials.

### CROSS REFERENCE

The present Application for Patent claims priority to U.S. Patent Application Ser. No. 63/702,982 by Brewer, entitled “THERMAL DISTRIBUTION LAYERS IN STACKED SEMICONDUCTOR ARCHITECTURES,” filed Oct. 3, 2024, which is assigned to the assignee hereof, and which is expressly incorporated by reference in its entirety herein.

### TECHNICAL FIELD

The following relates to one or more semiconductor systems, including thermal distribution layers in stacked semiconductor architectures.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports thermal distribution layers in stacked semiconductor architectures in accordance with examples as disclosed herein.

FIG. 2 shows an example of a system that supports thermal distribution layers in stacked semiconductor architectures in accordance with examples as disclosed herein.

FIG. 3 shows an example of a semiconductor system that supports thermal distribution layers in stacked semiconductor architectures in accordance with examples as disclosed herein.

FIG. 4A through 4G illustrate examples of operations that support thermal distribution layers in stacked semiconductor architectures in accordance with examples as disclosed herein.

FIG. 5A through 5I illustrate examples of operations that support thermal distribution layers in stacked semiconductor architectures in accordance with examples as disclosed herein.

FIG. 6 shows an example of a semiconductor system that supports thermal distribution layers in stacked semiconductor architectures in accordance with examples as disclosed herein.

FIGS. 7 and 8 show flowcharts illustrating a method or methods that support thermal distribution layers in stacked semiconductor architectures in accordance with examples as disclosed herein.

### DETAILED DESCRIPTION

Some semiconductor systems (e.g., memory systems, processor systems, systems having a combination of memory and processing) may include a stack of semiconductor components (e.g., semiconductor dies), which may include one or more memory dies (e.g., dynamic random access memory (DRAM) dies, memory array dies, array dies, memory dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets”(e.g., logic chiplets), among other examples.

Stacking semiconductor dies (e.g., DRAM dies, logic dies, host dies) for some applications may enhance performance and reduce the footprint of electronic devices. However, such an approach may increase power density (e.g., due to the closely-coupled dies which each generate heat), leading to thermal management challenges. For instance, as a quantity of stacked dies increases, heat generation within the stacked system may also increase. Accordingly, efficient heat dissipation may be desired to maintain the reliability and performance of such densely packed semiconductor systems. In some cases, voltage regulation and routing techniques may be used for thermal dissipation. However, such techniques may not sufficiently dissipate heat for stacked semiconductor systems (or other systems). Some semiconductor systems may experience significant thermal accumulation during operation, which may lead to hot spots in the system, performance degradation, and thermal-induced failures, among other challenges.

In accordance with one or more aspects described herein, a semiconductor system (e.g., a semiconductor device, an HBM device, a 3D stacked memory device, a stacked processing device, or other stacked system) may incorporate one or more layers of material that have a relatively high thermal conductivity (e.g., a high thermally conductive dielectric (HTCD) material, a HTCD interlayer, a dielectric material having a higher thermal conductivity than other materials of the semiconductor dies). For example, a stacked system may incorporate an HTCD material formed between or bonded between at least some of the semiconductor dies in the stack. The HTCD material may include conductor portions (e.g., vias, interconnects) through the material that facilitate a communicative coupling between the semiconductor dies. The HTCD materials between dies may improve heat dissipation by reducing overall thermal resistance of the stacked materials (e.g., supporting a more-uniform temperature distribution with reduced hot spots, increasing heat rejection from the stack). Such HTCD interlayers may be compatible with die bonding techniques such as hybrid bonding, standard wire bonding, and micro bumping, among other examples. The stacked semiconductor systems described herein may be manufactured based on various techniques, such as prefabrication of the HTCD materials (e.g., fabrication of a wafer or die of HTCD material), deposition of the HTCD material over a semiconductor die, and other examples. Accordingly, by including the HTCD material, a system may be provided with improved thermal performance that supports improved reliability and scaling, among other benefits.

In addition to applicability in memory systems as described herein, techniques for may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by supporting relatively higher processing and power density capabilities, thus supporting faster processing bandwidth, increased data transfer speeds, and improved reliability, among other benefits.

Features of the disclosure are illustrated and described in the context of systems and architectures. Features of the disclosure are further illustrated and described in the context of devices and flowcharts.

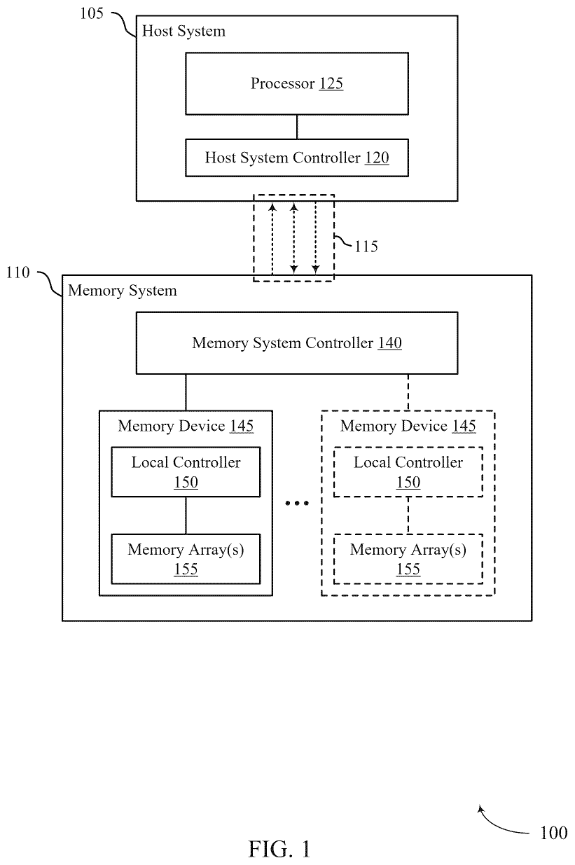

FIG. 1 shows an example of a system 100 that supports thermal distribution layers in stacked semiconductor architectures in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a 3D stacked memory system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

Some systems 100, or components thereof (e.g., a host system 105 or portion thereof, a memory system 110 or portion thereof) may be associated with thermal management challenges, and effective heat dissipation may be desired to maintain the reliability and performance of one or more portions of a system 100. In some cases, voltage regulation and routing techniques may be considered for thermal dissipation, but such techniques alone may not sufficiently dissipate heat for the system 100. Thus, a system 100 may experience, hot spots, performance degradation, and thermal-induced failures, among other effects. In accordance with one or more aspects described herein, one or more components of a system 100 (e.g., a semiconductor device, an HBM device, a 3D stacked memory device, a stacked processing device, or other stacked system) may be manufactured with one or more layers of material that have a relatively high thermal conductivity (e.g., one or more HTCD interlayers). An HTCD material may include conductor portions (e.g., vias, interconnects) that facilitate a bond (e.g., a communicative bond, a communicative coupling) between at least some of the semiconductor dies in the stack. HTCD materials between the dies may improve heat dissipation by reducing overall thermal resistance of the stacked materials (e.g., supporting a more-uniform temperature distribution with reduced hot spots, increasing a lateral heat rejection from the stack). Accordingly, by including the HTCD material, a system 100, or one or more components thereof, may be provided with improved thermal performance that supports improved reliability and scaling, among other benefits.

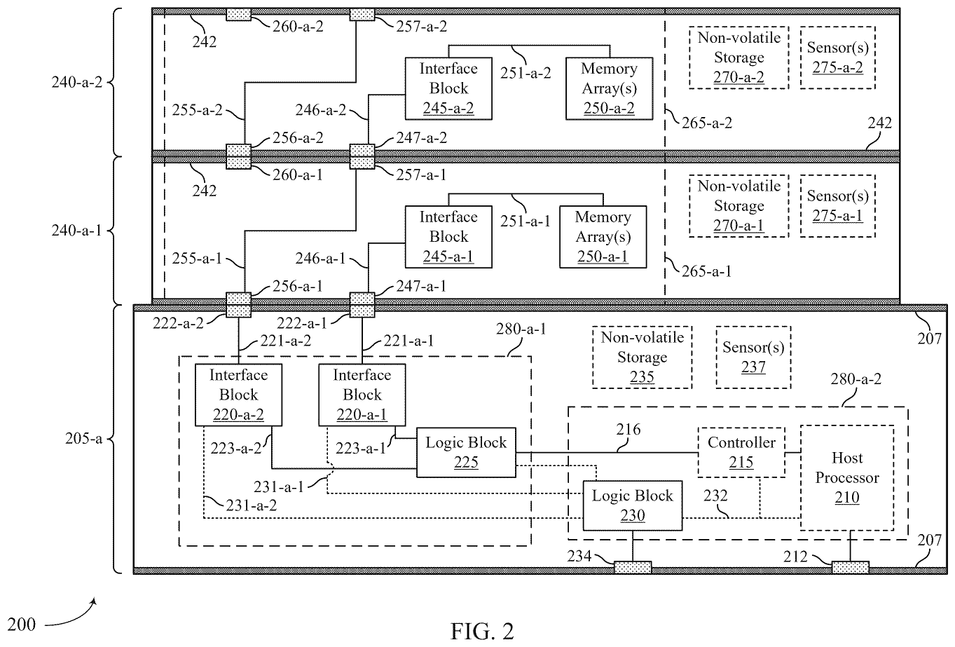

FIG. 2 shows an example of a system 200 (e.g., a semiconductor system, a system of coupled semiconductor dies, an HBM system, a 3D stacked memory system) that supports thermal distribution layers in stacked semiconductor architectures in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory implementations), a die 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 die and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

Some systems 200 may be associated with thermal management challenges, and effective heat dissipation may be desired to maintain the reliability and performance of the system 200. In some cases, voltage regulation and routing techniques may be used for thermal dissipation, but such techniques alone may not sufficiently dissipate heat for the system 200. Thus, a system 200 may experience, hot spots, performance degradation, and thermal-induced failures, among other effects. In accordance with one or more aspects described herein, a system 200 may be manufactured with one or more layers (e.g., HTCD interlayers) of material that have a relatively high thermal conductivity. For example, an HTCD material may include conductor portions (e.g., vias, interconnects) that facilitate a bond between other dies in the stack (e.g., between dies 240, between a die 240 and a die 205, for coupling with or between contacts 222, 247, 256, 257, or 260, or any combination thereof). For example, conductor portions of an HTCD interlayer may facilitate a coupling (e.g., an electrical coupling, a communicative coupling) between respective contacts 256 and contacts 260, between contacts 247 and contacts 257, or other communicative interfaces or combinations thereof of the dies. HTCD materials between dies of a system 200 may improve heat dissipation by reducing overall thermal resistance of the stacked materials (e.g., supporting a more-uniform temperature distribution with reduced hot spots, increasing a lateral heat rejection from the stack). Accordingly, by including the HTCD material, a system 200 may be provided with improved thermal performance that supports improved reliability and scaling, among other benefits.

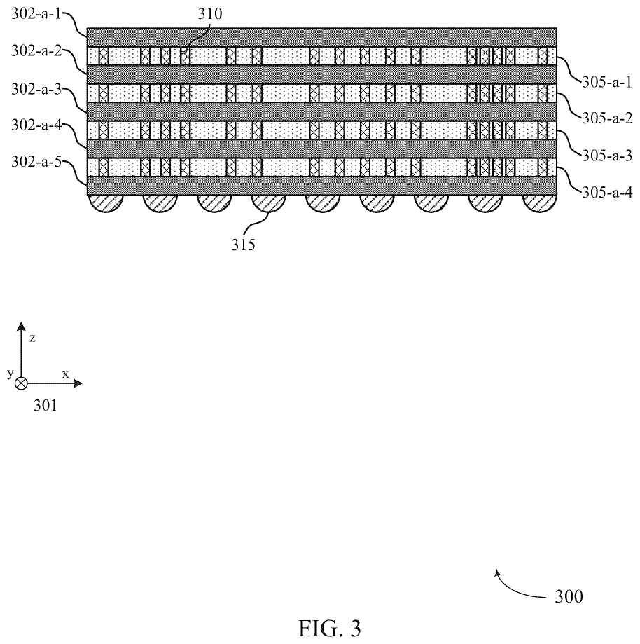

FIG. 3 shows an example of a semiconductor device 300 (e.g., a semiconductor system, a stacked semiconductor system) that supports thermal distribution layers in stacked semiconductor architectures in accordance with examples as disclosed herein. The semiconductor device 300 may be an example of or include one or more aspects of a system 100 or a system 200, and may be described with reference to an x-direction, a y-direction, and a z-direction of a coordinate system 301. A semiconductor device 300 may include a stack of components that includes dies 302 (e.g., dies 302-a-1 through 302-a-5, semiconductor dies) and dielectric materials 305 (e.g., dielectric materials 305-a-1 through 305-a-4). Each of the dies 302 may be an example of a die 205, a die 240, or another configuration of a semiconductor die. For example, in an HBM or a 3D stacked memory implementation, a semiconductor device 300 may include one or more dies 302 that each correspond to a die 205 and one or more dies 302 that each correspond to a die 240. In some other examples, each of the dies 302 of a semiconductor device 300 may correspond to a die 205, or each of the dies 302 of a semiconductor device 300 may correspond to a die 240, among other implementations. A semiconductor device 300 may also include conductors 310 (e.g., vias, interconnects) in at least some of the dielectric materials 305, and one or more contacts 315 (e.g., micro bumps, solder contacts, solder balls). In some examples, contacts 315 may facilitate electrical connections (e.g., bonding, coupling) with other electrical devices (e.g., including other semiconductor devices 300).

Although, the semiconductor device 300 is illustrated with a non-limiting example configuration of components, a semiconductor device 300 may support various configurations, including more or fewer dies 302, dielectric materials 305, conductors 310, and contacts 315, different types of dies (e.g., one or more processor core dies, a host die, a GPU die), or different stack ordering (e.g., two or more dies 302 stacked over a dielectric material 305, two or more dielectric materials 305 stacked over a die 302, and so on).

In some cases, stacking dies 302 for some packaging applications may increase power density, which can lead to reliability issues resulting from poor thermal management. That is, as more dies 302 are stacked within a semiconductor device 300, heat generated by each die 302 may accumulate (e.g., due to an increasing thermal resistance along the z-direction), creating hot spots and elevating an overall temperature of the semiconductor device 300. Such thermal buildup may adversely affect the performance and reliability of the components of a semiconductor device 300, potentially leading to thermal-induced failures, reduced operational efficiency, and a shorter lifespan of the device. Although voltage regulation and routing (e.g., routing of conductor materials) may offer some improvements in thermal performance, these measures may be insufficient to address the increased thermal challenges posed by high-density die stacking.

In accordance with one or more techniques described herein, a semiconductor device 300 may incorporate additional materials (e.g., additional layers of materials) to improve thermal management, thus enabling improved device performance and scaling. For example, a dielectric material 305 (e.g., an HTCD material, a coupling component) may be incorporated between at least some of (e.g., each of) the dies 302 of the stack. The dielectric materials 305 may have a relatively higher thermal conductivity than the materials of the dies 302 (e.g., silicon materials, semiconductor oxides, dielectric materials of the die 302), which may reduce resistance of heat flow in the device 300 and facilitate lateral heat dissipation (e.g., along the x-direction, along the y-direction, or both). Additionally, the dielectric materials 305 may electrically insulate at least a portion of a first die 302 (e.g., a die 302-a-1) from a second die 302 (e.g., a die 302-a-2), thus mitigating degradation in electrical performance. In some examples, a dielectric material 305 may be referred to as a coupling component, an HTCD material, an HTCD interlayer. An “interlayer” may refer a material layer that is positioned (e.g., bonded, situated, located) between two other layers (e.g., material layers, semiconductor component layers).

In some examples, one or more HTCD interlayers may be a prefabricated material (e.g., a ceramic layer) that include various conductors 310 (e.g., interconnects, vias, metals such as copper, aluminum, tungsten). For example, a dielectric material 305 (e.g., multiple HTCD interlayers for stacking) may be separated from (e.g., cut, diced, singulated) a wafer including multiple dielectric materials 305 (e.g., multiple HTCD interlayer chiplets). Accordingly, such prefabricated dielectric materials 305 may be handled and stacked similar to dies 302. That is, the HTDC Interlayer may be compatible with various bonding techniques, such as hybrid bonding (e.g., a bond of respective dielectric materials and respective conductor materials), fusion bonding, thermocompression bonding (TCB), micro bump bonding (e.g., solder connections). For example, an HTCD interlayer (e.g., a 305-a-2) may be bonded between dies 302 (e.g., die 302-a-2 and die 302-a-3) based on an alignment of the conductor 310 with respective contacts (not shown) of the dies 302, such as bond pads, vias, or other conductive materials. Additionally, or alternatively, one or more dielectric materials 305 (e.g., the dielectric material 305-a-4) may be deposited over a first die 302 (e.g., a die 302-a-5) and a second die 302 (e.g., a die 302-a-4) may be bonded to the deposited HTCD interlayer. Accordingly, an addition of the dielectric materials 305 may improve heat dissipation of the semiconductor device 300 by being an effective conduit for thermal energy to move to the edges (e.g., lateral edges) of the semiconductor device 300.

A bonding (e.g., a fusion bond, a hybrid bond) between the dies 302 and a dielectric materials 305 may increase contact between materials of stacked dies 302 and relatively higher thermal conductive material, enhancing thermal performance. For example, contact with the dielectric materials 305 may provide more area for heat to dissipate from the semiconductor device 300. In other words, the contact of the conductor portions of the dies 302, the conductors 310, and the other materials of the dies 302 with the dielectric materials 305 may provide increased surface area to move heat to the HTCD interlayers, which may more efficiently move heat to the edges of the stack, reducing thermal resistance and improving overall heat dissipation.

The dielectric materials 305 may include one or more materials (e.g., that form its substrate) that satisfy one or more threshold metrics associated with an electrical insulation, a mechanical stability, a thermal conductivity, or any combination thereof. For example, the dielectric materials 305 may include an aluminum nitride material (e.g., having a thermal conductivity of 200 watts per meter per degree Kelvin (Wm-¹K⁻¹) or greater), a silicon carbide material (e.g., having a thermal conductivity of 252-270 Wm-¹K⁻¹ or greater), a silicon nitride material (e.g., having a thermal conductivity of 177 Wm-¹K⁻¹ or greater), a boron arsenide material (e.g., having a thermal conductivity of around 1200 Wm-¹K⁻¹ or greater), or a combination thereof. Such materials may have a greater thermal conductivity than other dielectric materials of the dies 302, such as a silicon oxide (e.g., silicon dioxide, having a thermal conductivity of around 1-2 Wm-¹K⁻¹), among other dielectric materials that may be implemented in dies 302.

Although the addition of dielectric materials 305 may increase thermal resistance of a semiconductor device 300 along the z-direction (e.g., compared with the absence of including dielectric materials 305), the dielectric materials 305 may support a net improvement to the thermal condition of the semiconductor device 300. For example, dielectric materials 305 may support increased heat flow (e.g., reduced thermal resistance) in an xy-plane (e.g., along the x-direction, along the y-direction, along a direction between the x-direction and y-direction), which may support a reduction in hot spots (e.g., a more-uniform temperature distribution) and an increase in overall heat flux through a cross-section of the semiconductor device 300 in the xy-plane (e.g., along the z-direction). Such effects may improve heat rejection through a heat sink (not shown) above or below the semiconductor device 300, or may support a higher net power operation by reducing the temperature of local hot spots. Further, such techniques may support lateral heat rejection from the semiconductor device 300, such as through surfaces of the dielectric materials 305 in an xz-plane, a yz-plane, or both, or through projections (e.g., fins, beyond extents of the dies 302) of the dielectric materials 305 along one or more directions in an xy-plane, or any combination thereof, which may reduce amount of heat that is rejected along the z-direction (e.g., for a given operating power or peak temperature).

Thus, by incorporating dielectric materials 305 (e.g., HTCD interlayers), a semiconductor device 300 may support relatively higher capacity or throughput (e.g., higher storage capacity, a larger quantity of dies 302, higher power operation, higher processing speed) in die-stacked products. That is, dielectric materials 305 may enable improved thermal management that supports an increased power density without adversely affecting device performance and reliability. Additionally, by maintaining relatively lower and more uniform temperatures, the dielectric materials 305 may reduce a risk of thermal-induced failures and degradation. Further, mechanical stability provided by dielectric materials 305 may enhance the structural integrity of the die stack, reducing a likelihood of mechanical failures. Moreover, dielectric materials 305 may support improved data rates by maintaining sufficient thermal conditions for high-speed operation (e.g., allowing the dies 302 to operate at relatively higher frequencies).

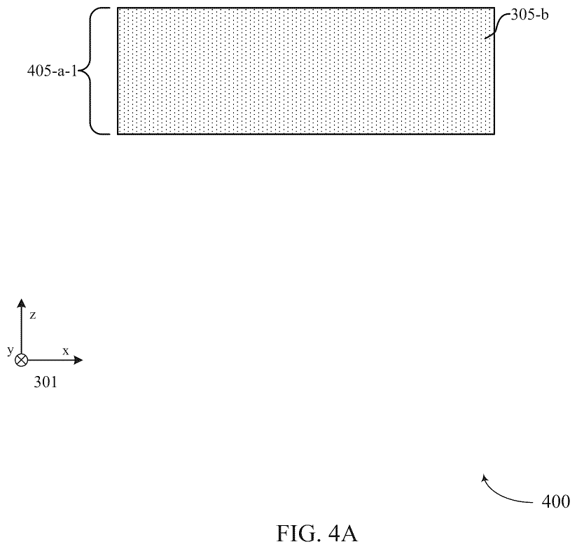

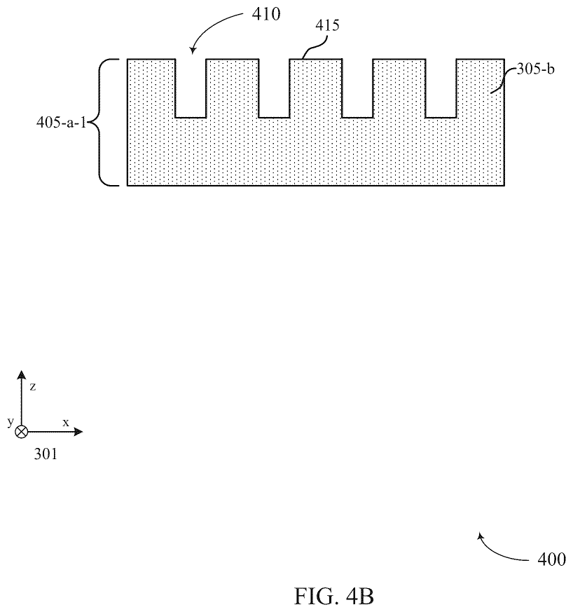

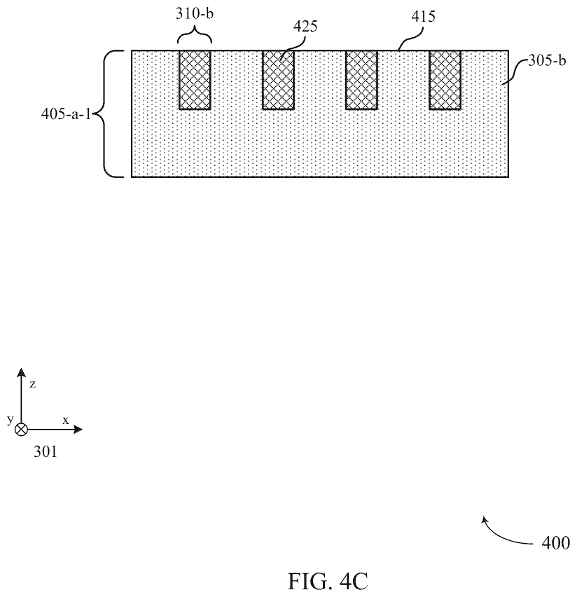

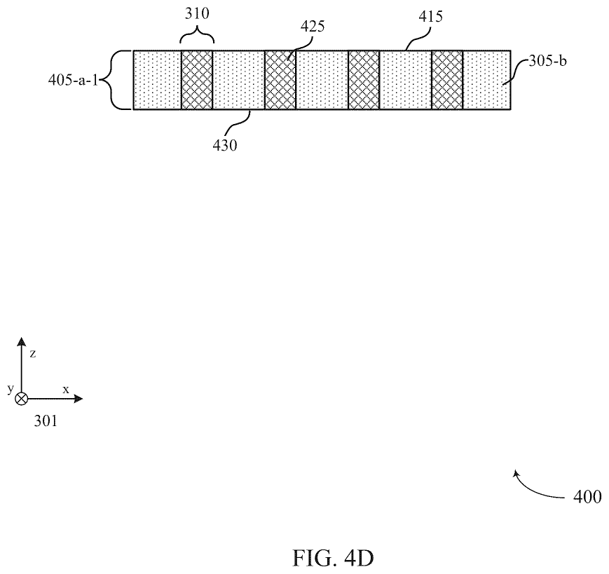

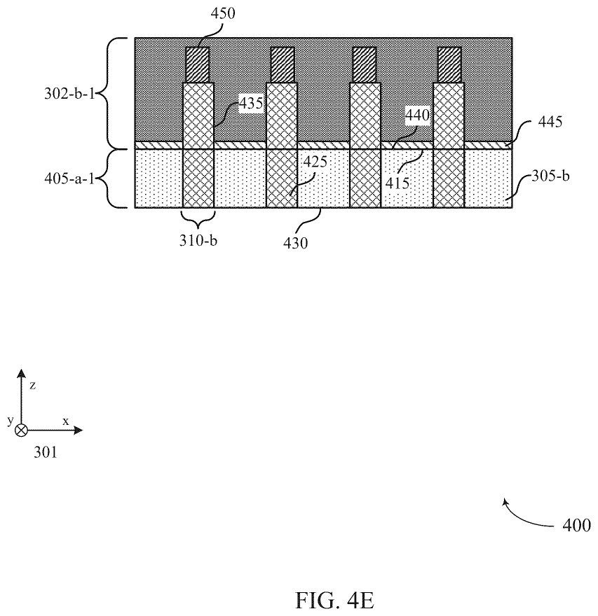

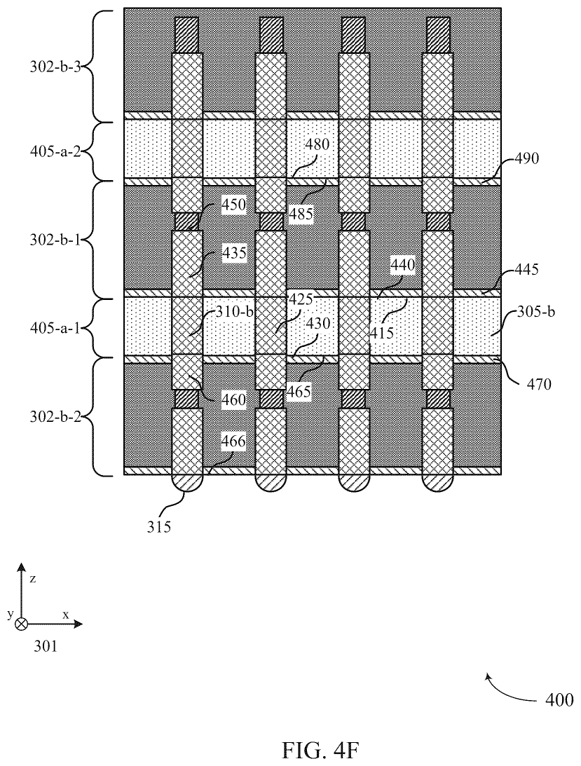

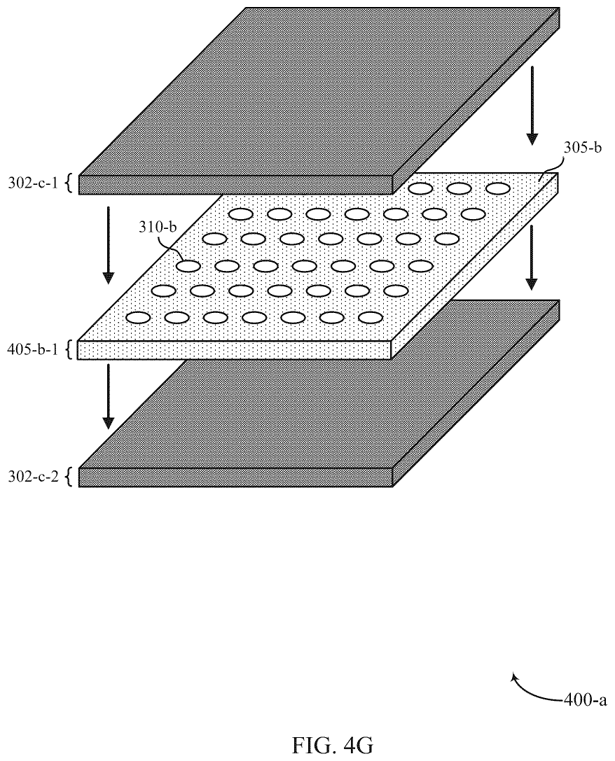

FIGS. 4A through 4F illustrate examples of operations that support thermal distribution layers in stacked semiconductor architectures in accordance with examples as disclosed herein. For example, FIGS. 4A through 4G may illustrate techniques for prefabrication of HTCD interlayers. Operations are illustrated with reference to a device 400, which may be an example of or include an electronic device (e.g., a semiconductor device 300, a system 100, a memory system 110, a host system 105, a system 200), or portion thereof. For example, FIGS. 4A through 4G may illustrate aspects of a first sequence of operations that support manufacturing a system 100 or a portion thereof, a system 200 or a portion thereof, a semiconductor device 300 or a portion thereof, or some other device. Each of the figures may be described with reference to an x-direction, a y-direction, and a z-direction of a coordinate system 301. Operations illustrated in and described with reference to FIGS. 4A through 4G may be performed by a manufacturing system, such as a semiconductor fabrication system configured to perform additive operations (e.g., deposition, epitaxy, bonding), subtractive operations (e.g., etching, trenching, planarizing, polishing, grinding, scraping), modifying operations (e.g., oxidizing, doping, reacting, converting), and supporting operations (e.g., masking, patterning, photolithography, aligning), among other operations that support the described techniques.

In some examples, portions of the device 400 that are illustrated with a same fill pattern may be formed of same or similar materials and portions that are illustrated with different patterns may be formed of different materials. Various dielectric materials are described herein, which may include an aluminum nitride, a silicon carbide, a silicon oxide, a silicon nitride, a silicon carbon nitride, a tetraethyl orthosilicate (TEOS), a boron arsenide, some other dielectric material, or any combination thereof. Additionally, conductive materials described herein may include copper, aluminum, tungsten, titanium, some other conductive material, or any combination thereof.

FIG. 4A shows an example of a cross-sectional view of the device 400 after a first set of one or more fabrication operations. For example, the first operations may include forming a coupling component 405-a-1 (e.g., an HTCD interlayer) with a dielectric material 305. That is, forming the coupling component 405-a-1 may include forming the dielectric material 305-b of the coupling component 405-a-1. In some examples, forming the dielectric material 305-b may include forming a wafer (e.g., to be singulated into some quantity of multiple portions) that includes a set of multiple coupling components 405 (not shown) formed of respective dielectric materials 305 including the coupling component 405-a-1. In some examples, the dielectric material 305 may include aluminum nitride, silicon carbide, silicon nitride, or boron arsenide.

FIG. 4B shows an example of a cross-sectional view of the device 400 after a second set of one or more fabrication operations. For example, the second operations may include forming a set of one or more cavities 410 into a surface 415 of the dielectric material 305-b (e.g., of the coupling component 405-a-1). In some examples, the second operations may include a patterning of the coupling component 405-a-1 and etching of the cavities 410 (e.g., or some other material removal technique to form the cavities 410), which may result in the formation of the cavities 410. The coupling component 405-a-1 may include any quantity of cavities 410, including more or fewer cavities 410 than shown. At this stage, in some examples, the coupling component 405-a-1 may not yet be separated from the wafer of multiple coupling components 405 (e.g., may still be part of the larger wafer).

FIG. 4C shows an example of a cross-sectional view of the device 400 after a third set of one or more fabrication operations. For example, the third operations may include forming a set of one or more conductors 310-b (e.g., vias, contacts, interconnects) based on forming a conductive material 425 in each of the cavities 410 (e.g., at the surface 415). In some examples, forming the conductors 310-b may be based on a deposition operation and/or a plating operation (e.g., using a metal material). In some examples, the conductive material 425 may include a metal material (e.g., copper).

FIG. 4D shows an example of a cross-sectional view of the device 400 after a fourth set of one or more fabrication operations. For example, the fourth operations may include removing (e.g., grinding, thinning, cutting, etching, planarizing, chemical mechanical planarization (CMP), wafer thinning) a portion of the dielectric material 305-b to expose the conductors 310-b at a surface 430 of the coupling component 405-a-1. In some examples, the removal of the portion of the dielectric material 305-b may be associated with achieving a target interlayer thickness (e.g., along the z-direction, a HTCD layer thickness, a die thickness). In some examples, after the coupling component 405-a-1 has been thinned to expose the conductors 310-b at the surface 430, one or more coupling components 405 including the coupling component 405-a-1 may be separated (e.g., diced, cut, based on die cutting) from the wafer of coupling components (not shown) as part of the fourth operations. In some examples, based on the fourth operations, the coupling component 405-a-1 (e.g., a separated interlayer die) may be ready for integration into a stacked system and may be compatible with various bonding techniques.

FIG. 4E shows an example of a cross-sectional view of the device 400 after a fifth set of one or more fabrication operations. For example, the fifth operations may include bonding (e.g., hybrid bonding, post bonding with lower force) a die 302-b-1 (e.g., a first semiconductor component) with the surface 415 of the coupling component 405-a-1. In some examples, the die 302-b-1 may be singulated from a wafer of dies 302 (e.g., in a die-to-die bonding operation, in a die-do-wafer operation), or may be included as part of multiple dies 302 of a wafer (e.g., before singulation, in a wafer-to-wafer bonding operation). The bonding may be based on bonding the conductors 310-b of the coupling component 405-a-1 with a set of contacts 435 (e.g., conductors, bond pads) of the die 302-b-1 at a surface 440 of the die 302-b-1 (e.g., based on a post-anneal to form metal interconnects). The contacts 435 may be formed of the conductive material 425 or a different conductive material. The contacts 435 may also be coupled with other contacts 450 (e.g., TSVs, back end of line (BEOL) circuitry, interconnection circuitry), which may be formed of a different conductive material than the conductive material 425, or may be the same as the conductive material 425.

In some examples, the bonding may be based on bonding the dielectric material 305-b of the coupling component 405-a-1 with a dielectric material 445 at the surface 440 of the die 302-b-1. That is, in some examples, a hybrid bonding technique may be used for a direct bonding of a die 302 (e.g., a silicon die) and a coupling component 405-a-1 (e.g., an HTCD interlayer). In some examples, a thermal conductivity of the dielectric material 305-b may be higher than a thermal conductivity of the dielectric material 445. In some examples, the dielectric material 445 may include a silicon oxide or some other dielectric material (e.g., different than the dielectric material 305). In some other examples, the dielectric material 445 may be the same as the dielectric material 305-b, which may be a layer of the same dielectric material that is formed on the die 302-b-1 prior to the fifth operations (e.g., as a layer that may be thinner than the coupling component 405-a-1, as a layer to facilitate bond integrity between the die 302-b-1 and the coupling component 405-a-1).

In some examples, the contacts 435 and the other contacts 450 may be coupled with circuitry (not shown) of the die 302-b-1 (e.g., interface blocks 245, memory arrays 250, non-volatile storage 270, sensors 275, for an example in which the die 302-b-1 corresponds to a die 240). The circuitry of the die 302-b-1 may include (e.g., be included in) a doped portion of a semiconductor substrate (e.g., a silicon material, a crystalline substrate, a substrate over which front end of line layers or back end of line layers are formed) of the die 302-b-1. In some examples, the circuitry of the die 302-b-1 may include circuitry associated with accessing a first memory array of the die 302-b-1. In some examples, contacts 450 may not be exposed during the fifth operations (e.g., may be underneath a layer of dielectric material 445, as shown). In some other examples, contacts 450 may be exposed during the fifth operations (not shown).

FIG. 4F shows an example of a cross-sectional view of the device 400 after a sixth set of one or more fabrication operations. For example, the sixth operations may include bonding a die 302-b-2 (e.g., a second semiconductor component) with a surface 430 of the coupling component 405-a-1, which may be opposite the surface 415. The bonding may be based on bonding the conductors 310-b of the coupling component 405-a-1 with a set of contacts 460 (e.g., bond pads, conductors) of the die 302-b-2 at a surface 465 of the die 302-b-2. Additionally, the bonding may be based on bonding the dielectric material 305-b of the coupling component 405-a-1 with a dielectric material 470 at the surface 465 of the die 302-b-2. In some examples, the thermal conductivity of the dielectric material 305-b may be higher than a thermal conductivity of the dielectric material 470 (e.g., which may be a same material as the dielectric material 445 or a different material).

In some examples, the dielectric material 305-b that is bonded with the dielectric material 445 may be contiguous with the dielectric material 305 bonded with the dielectric material 470 (e.g., the dielectric materials 305 may span along the z-direction from a dielectric of a first die 302 to a dielectric of a second die 302). In some examples, circuitry of the 302-b-1 may be coupled with circuitry (not shown) of the die 302-b-2 via one or more of the conductors 310-b. In some examples, the circuitry of the die 302-b-2 may include a doped portion of a semiconductor substrate of the die 302-b-2. In some examples, the circuitry of the die 302-b-2 may include circuitry associated with accessing a second memory array of the die 302-b-2.

In some examples, the sixth operations may include subsequent bonding operations between one or more dies 302 and coupling components 405. For example, the sixth operations may include bonding the die 302-b-1 with a surface 480 of a coupling component 405-a-2 based on bonding a set of conductors 310-b of the coupling component 405-a-2 with a set of contacts 450 of the die 302-b-2 at a surface 485 of the die 302-b-1 opposite the surface 440 of the die 302-b-1. Additionally, the bonding may be based on bonding the dielectric material 305-b of the coupling component 405-a-2 with a dielectric material 490 at the surface 485 of the die 302-b-1. A thermal conductivity of the dielectric material 305-b of the coupling component 405-a-2 may be higher than a thermal conductivity of the dielectric material 490 (e.g., which may be a same material as the dielectric materials 445 or 470. or a different material). The sixth operations also may include bonding a die 302-b-3 with the coupling component 405-a-2 based on one or more similar operations as described with reference to FIGS. 4A through 4F.

Thus, based on one or more manufacturing operations described herein, the device 400 may be fabricated to include a die 302-b-1 including first circuitry, where a surface 440 of the die 302-b-1 may include a dielectric material 445. The device 400 may include a die 302-b-2 including second circuitry, where a surface 465 of the die 302-b-2 may include a dielectric material 470. The semiconductor device 400 may include a third dielectric material 305-b (e.g., as at least a portion of a coupling component 405-a-1) between the die 302-b-1 and the die 302-b-2, where a surface 415 of the dielectric material 305 may be in contact with the surface 440 of the die 302-b-1, and a surface 430 of the dielectric material 305 opposite the surface 415 may be in contact with the surface 465 of the die 302-b-2. The semiconductor device 400 may include a set of conductors 310-b through the dielectric material 305-b, which may couple circuitry of the die 302-b-1 with circuitry of the die 302-b-2.

In some examples, the semiconductor device 400 may include a first set of contacts 435 of the die 302-b-1 that are respectively coupled with the conductors 310-b at the surface 440 of the die 302-b-1. Additionally, a second set of contacts 460 of the die 302-b-2 may be respectively coupled with the conductors 310 at the surface 465 of the die 302-b-2.

Thus, the circuitry of the die 302-b-1 may be coupled with the circuitry of the die 302-b-2 based on (e.g., via, by way of) the first set of contacts 435 and the second set of contacts 460. In some examples, the device 400 may include a set of contacts 315 (e.g., solder contacts, micro bumps, formed of conductive material) at a surface 466 of the die 302-b-2 opposite the surface 465 of the die 302-b-2.

By implementing one or more techniques herein, a device 400 may be manufactured with an increased ability to dissipate heat (e.g., based on relatively high thermal conductivity of the dielectric materials 305-b), increased performance based on reduced thermal stress, and may support relatively storage capacity and power density. For example, the described techniques may provide a relatively lower resistance area for heat flow to the lateral portions of the device 400, thus increasing surface area for heat dissipation. Moreover, by implementing the described techniques, a device 400 may have a relatively longer lifespan, which may result in reduced electronic waste and improved user experience, among other benefits.

FIG. 4G shows an example of a three-dimensional view of a device 400-a that supports thermal distribution layers in stacked semiconductor architectures in accordance with examples as disclosed herein. The die 302-c-1 may be stacked over a coupling component 405-b-2 (e.g., a prefabricated portion of dielectric material 305), which may be stacked over a die 302-c-2. These components may be bonded together based on wafer-to-wafer bonding (e.g., the die 302-c-1, the coupling component 405-b-2, and the die 302-c-2 may be part or respective wafers prior to bonding), chip-to-wafer bonding (e.g., at least one of the die 302-c-1, the coupling component 405-b-2, and the die 302-c-2 may be separated from a respective wafer prior to bonding), stack-to-wafer bonding (e.g., at least two of the die 302-c-1, the coupling component 405-b-2, and the die 302-c-2 may be bonded and separated from a wafer prior to bonding with other components). The stacked dies 302-c may be coupled based on multiple conductors 310-b (e.g., which may be arranged as an array of one or more rows and one or more columns to align with respective contacts of the dies 302-c).

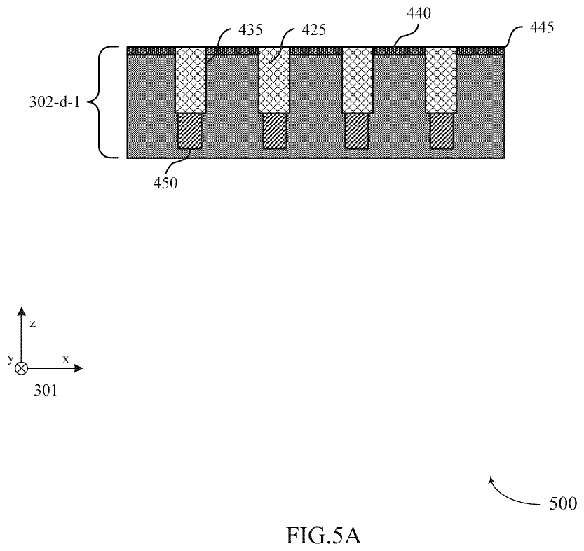

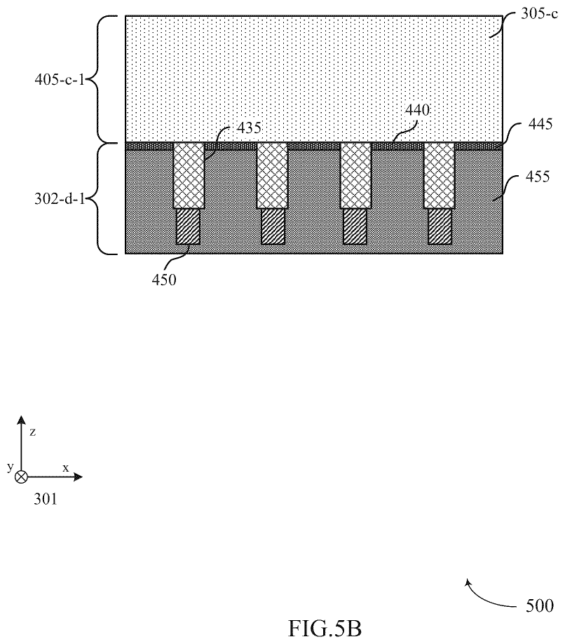

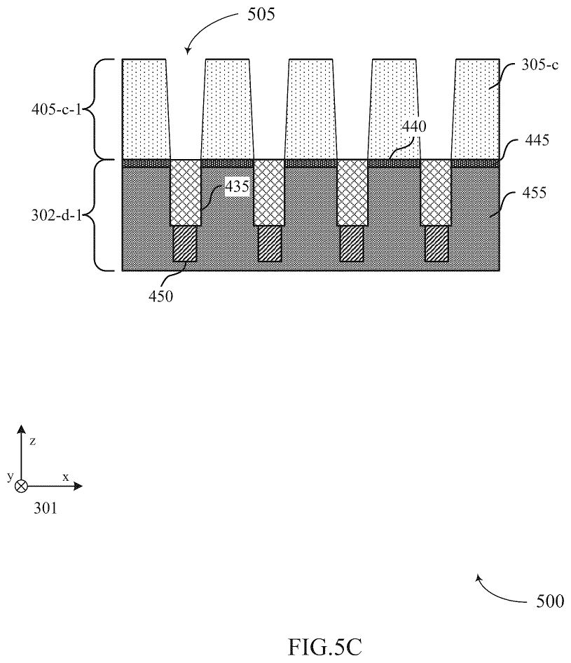

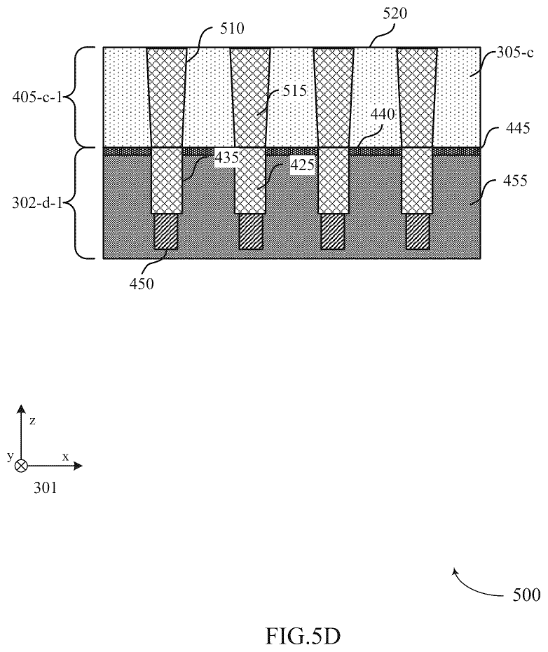

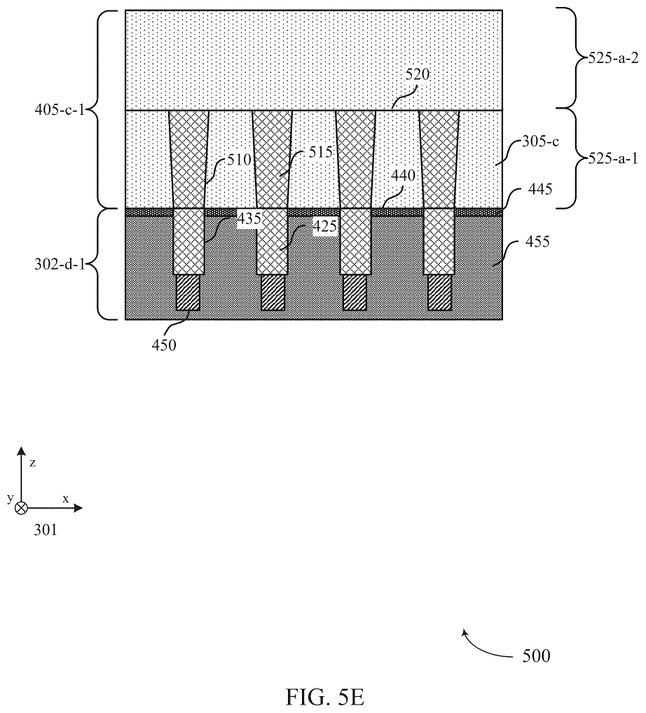

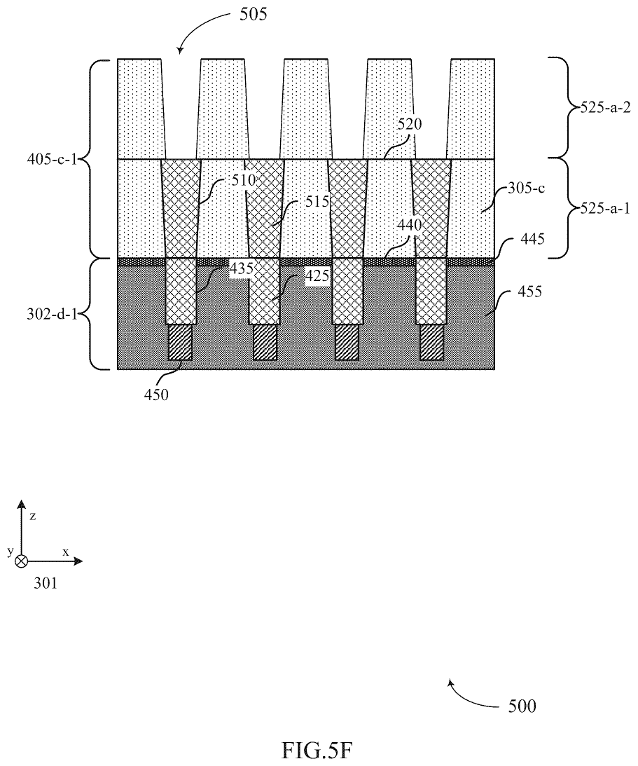

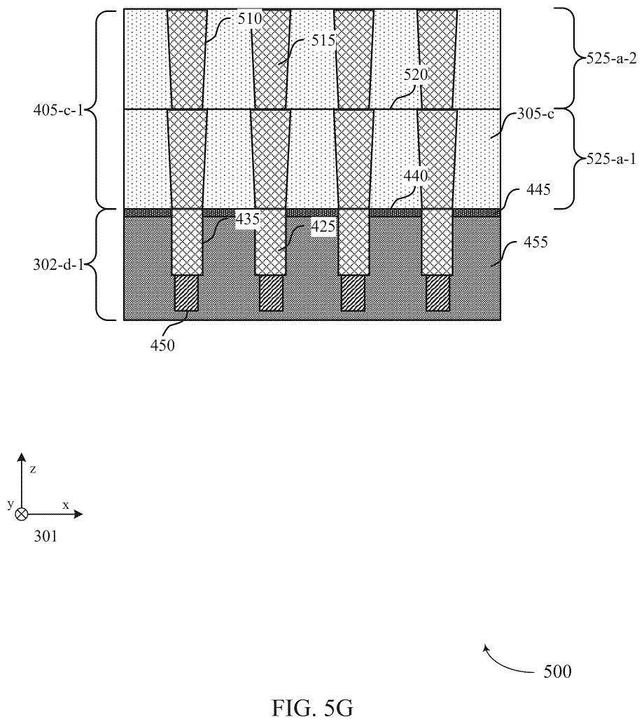

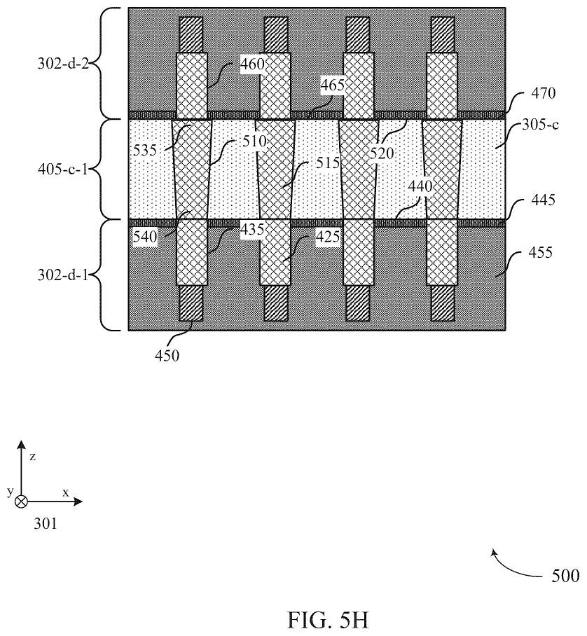

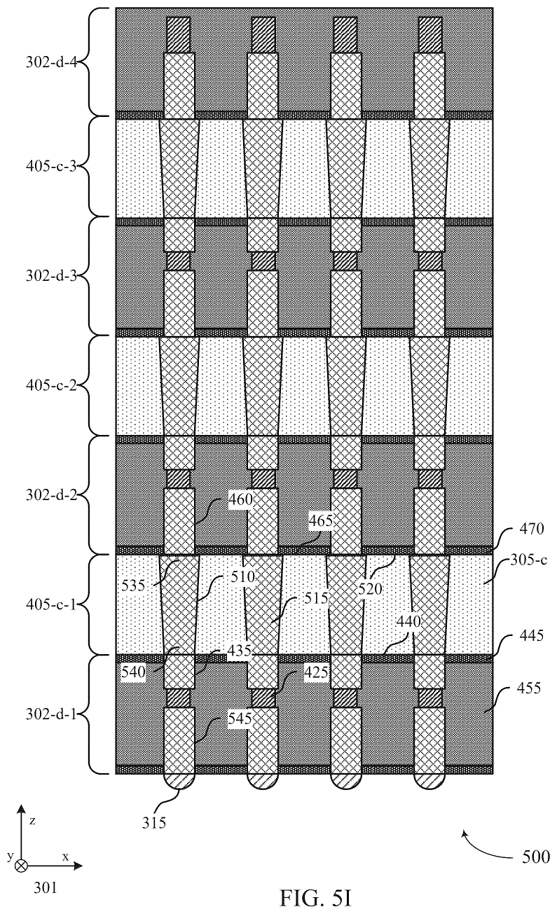

FIGS. 5A through 5I illustrate examples of operations that support thermal distribution layers in stacked semiconductor architectures in accordance with examples as disclosed herein. For example, FIGS. 5A through 5I may illustrate techniques for formation (e.g., deposition) of HTCD interlayers. Operations described with reference to FIGS. 5A through 5I may be performed in addition, or in alterative to the operations described with reference to FIGS. 4A through 4F. That is, one or more or more operations described as being performed with reference to FIGS. 4A through 4F may be performed (e.g., added) in any combination with the operations of FIGS. 5A through 5I, and vice-versa.

Operations are illustrated with reference to a device 500, which may be an example of or include an electronic device (e.g., a semiconductor device 300, a system 100, a memory system 110, a host system 105, a system 200). For example, FIGS. 5A through 5I may illustrate aspects of a first sequence of operations that support manufacturing a system 100 or a portion thereof, a system 200 or a portion thereof, a semiconductor device 300 or a portion thereof, or some other device. Each of the figures may be described with reference to an x-direction, a y-direction, and a z-direction of a coordinate system 301. Operations illustrated in and described with reference to FIGS. 5A through 5I may be performed by a manufacturing system, such as a semiconductor fabrication system configured to perform additive operations (e.g., deposition, epitaxy, bonding), subtractive operations (e.g., etching, trenching, planarizing, polishing, grinding, scraping), modifying operations (e.g., oxidizing, doping, reacting, converting), and supporting operations (e.g., masking, patterning, photolithography, aligning), among other operations that support the described techniques.

In some examples, portions of the device 500 that are illustrated with a same fill pattern may be formed of same or similar materials and portions that are illustrated with different patterns may be formed of different materials. Various dielectric materials are described herein, which may include an aluminum nitride, a silicon carbide, a silicon oxide, a silicon nitride, a silicon carbon nitride, a tetraethyl orthosilicate (TEOS), a boron arsenide, some other dielectric material, or any combination thereof. Additionally, conductive materials described herein may include copper, aluminum, tungsten, titanium, some other conductive material, or any combination thereof.

FIG. 5A shows an example of a cross-sectional view of the device 500 after a first set of one or more fabrication operations. For example, the first operations may include forming a die 302-d-1 (e.g., a first semiconductor component). In some examples, forming the die 302-d-1 may include forming circuitry that includes a doped portion of a semiconductor substrate of the die 302-d-1, circuitry as part of one or more front end of line layers, one or more back end of line layers, or any combination thereof, among other semiconductor circuitry. Forming the die may also include forming a dielectric material 445 (e.g., silicon oxide), contacts 435 (e.g., bond pads, first conductive materials) including conductive material 425 (e.g., copper), and contacts 450 (e.g., TSVs, second conductive materials). In some examples, the dielectric material 445 may be formed at a surface 440 of the die 302-d-1. The contacts 435 may be coupled with the circuitry of the die 302-d-1.

FIG. 5B shows an example of a cross-sectional view of the device 500 after a second set of one or more fabrication operations. For example, the second operations may include forming a coupling component 405-c-1. Forming the coupling component 405-c-1 may include forming a dielectric material 305-c over the surface 440 of the die 302-d-1 (e.g., as a material deposition operation, as a bonding operation). In some examples, forming the dielectric material 305-c may include a deposition of the dielectric material 305-c on the surface 440. In some examples, a deposition of the dielectric material 305-c may support relatively larger thicknesses (e.g., greater than a threshold thickness along the z-direction) than a prefabricated portion of dielectric material 305-c.

FIG. 5C shows an example of a cross-sectional view of the device 500 after a third set of one or more fabrication operations. For example, the third operations may include forming (e.g., trenching, etching) a set of cavities 505 through the dielectric material 305-c. For example, each cavity 505 may expose a respective contact 435 of the die 302-d-1 at the surface 440.

FIG. 5D shows an example of a cross-sectional view of the device 500 after a fourth set of one or more fabrication operations. For example, the fourth operations may include forming a set of conductors 510 (e.g., an alternative example of conductors 310) through the dielectric material 305-c. The conductors 510 may thus be in contact with the contacts 435 of the die 302-d-1 . In some examples, forming the conductors 510 may include forming a conductive material 515 in the cavities 505 (e.g., which may be a same material as the conductive material 425 or a different material than the conductive material 425). In some examples, a surface 520 of the dielectric material 305 may be planarized (e.g., polished) after forming the conductors 510.

FIG. 5E shows an example of a cross-sectional view of the device 500 after a fifth set of one or more fabrication operations, which may be optional based on a desired target thickness for the coupling component 405-c-1. For example, the fifth operations may include forming an additional thickness 525 of dielectric material 305. For example, the second operations (e.g., as described with reference to FIG. 5B) may include forming a thickness 525-a-1 of the dielectric material 305, which may be associated with respective first portions of the conductors 510. The fifth operations may include forming, after forming the thickness 525-a-1 and the respective first portions of the conductors 510, a thickness 525-a-2 of the dielectric material 305-c over the thickness 525-a-1.

FIG. 5F shows an example of a cross-sectional view of the device 500 after a sixth set of one or more fabrication operations, which may be optional based on a desired target thickness for the coupling component 405-c-1. For example, the sixth operations may include one or more repeated operations of the third operations (e.g., described with reference to FIG. 5C), where cavities 505 are formed in the thickness 525-a-2 of the dielectric material 305-c, exposing the conductors 510 at the surface 520.

FIG. 5G shows an example of a cross-sectional view of the device 500 after a seventh set of one or more fabrication operations, which may be optional based on a desired target thickness for the coupling component 405-c-1. For example, the seventh operations may include one or more repeated operations of the fourth operations (e.g., described with reference to FIG. 5C), where the conductors 510 (e.g., second portions of conductors 510) are formed in the thickness 525-a-2, which may be associated with respective second portions of the conductors 510 in contact with the respective first portions of the conductors 510 included in the thickness 525-a-1.

In some examples, the fifth, sixth, and seventh operations may be subsequently repeated to form additional thicknesses 525 of the coupling component 405-c-1 (e.g., according to a target thickness). Moreover, the repeated operations for forming dielectric material 305 and conductors 510 may increase a thickness of the coupling component 405-c-1 (e.g., the deposited HTCD interlayer), which may further improve thermal performance of a final die stack. Additionally, such techniques may allow a height of the device 500 to be configured based on an application of the device 500 (e.g., to achieve a target height along the z-direction).

FIG. 5H shows an example of a cross-sectional view of the device 500 after an eighth set of one or more fabrication operations (e.g., which may illustrate a non-limiting example in which no additional thicknesses 525 are added). For example, the eighth operations may include bonding a die 302-d-2 (e.g., a second semiconductor component) with the surface 520 of dielectric material 305-c that is opposite the die 302-d-1. In some examples, bonding the die 302-d-2 may be based on bonding the conductors 510 with a set of contacts 460 at a surface 465 of the die 302-d-2. Additionally, or alternatively, bonding the die 302-d-2 may be based on bonding the dielectric material 305-c with a dielectric material 470 at the surface 465 of the die 302-d-2. In some examples, circuitry (not shown) of the die 302-d-1 may be coupled with circuitry (not shown) of the die 302-d-2 via one or more of the conductors 510. In some examples (e.g., based on the formation of cavities 505), a first end 535 of at least one conductor 510 may have a larger width than a second end 540 of at least one of the conductors 510.

FIG. 5I shows an example of a cross-sectional view of the device 500 after a ninth set of one or more fabrication operations. For example, the ninth operations may include forming set of solder contacts 315 (e.g., at one end of the die stack), which may be coupled with respective contacts 545 (e.g., bond pads) of the die 302-d-1. Accordingly, the respective circuitries of each die 302-d may be accessed based on the solder contacts 315. Moreover, the ninth operations may include one or more repeated operations of the first operations through the eighth set of operations (e.g., as described with reference to FIGS. 5A through 5H). That is, the ninth operations may include forming a coupling component 405-c-2, a die 302-d-3, a coupling component 405-c-3, and a die 302-d-4, and bonding the components together in accordance with one or more techniques described herein.

Thus, by implementing one or more techniques herein, a device 500 may be manufactured with an increased ability to dissipate heat (e.g., based on relatively high thermal conductivity of the dielectric materials 305-c), an increased performance based on reduced thermal stress, and may support relatively storage capacity and power density. For example, the described techniques may provide a relatively lower resistance area for heat flow to the lateral portions of the device 500, thus increasing surface area for heat dissipation. Moreover, by implementing the described techniques, a device 500 may have a relatively longer lifespan, which may result in reduced electronic waste and improved user experience, among other benefits.

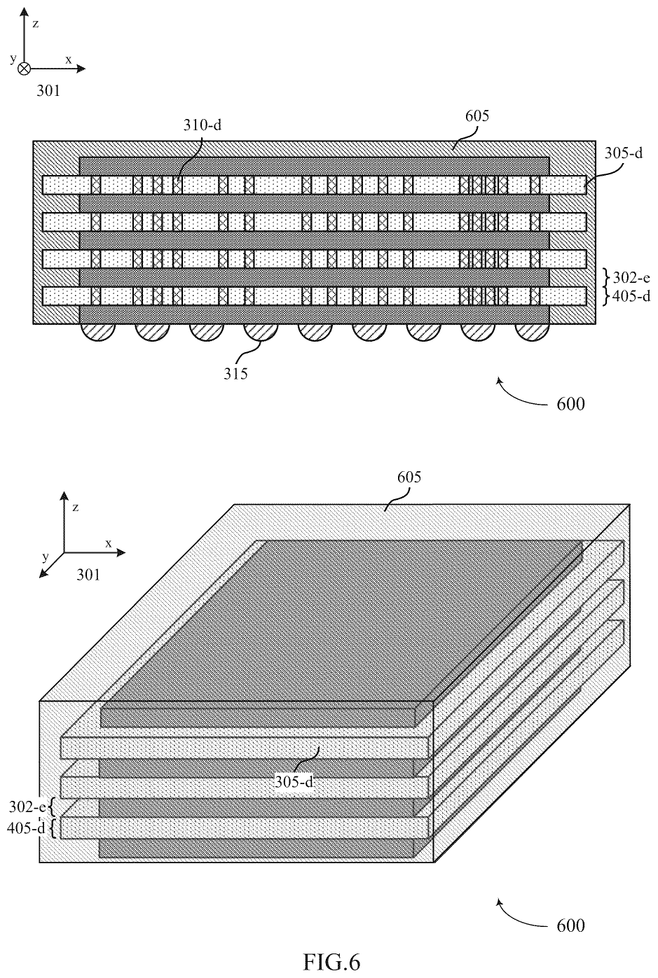

FIG. 6 shows an example of a device 600 (e.g., in a cross-sectional view and a transparent diagonal view) that supports thermal distribution layers in stacked semiconductor architectures in accordance with examples as disclosed herein. In some examples, the device 600 may be an example of or include an electronic device as described herein (e.g., a device 500, a device 400, a semiconductor device 300, a system 100, a memory system 110, a host system 105, a system 200). The upper illustration may be a cross-sectional view of the device 600, and the lower illustration may be a three-dimensional diagonal view of the device 600, each of which may be described with reference to an x-direction, a y-direction, and a z-direction of a coordinate system 301.

In some examples, one or more coupling components 405-d (e.g., HTCD interlayers) of the device 600 (e.g., or other device) may be relatively larger (e.g., oversized, along the x-direction, along the y-direction, in an xy-plane) compared to the dies 302-e (e.g., semiconductor dies, DRAM dies). For example, the coupling components 405 may create fins that extend beyond the dies 302-e, which may operate as heat sinks for the device 600. In some examples, configuring the coupling components 405-d to be larger than the dies 302-e at the edges of the stack may further improve heat dissipation, such as by increasing a volume, extent, or surface area of the dielectric material 305-d (e.g., adding or extending the dielectric material 305-d along one or more directions in an xy-plane). Such techniques may improve heat dissipation by reducing thermal resistance along one or more directions in an xy-plane, by extending surfaces in one or more xy-planes from which heat may be dissipated, by providing greater heat dissipation between dies 302-e, by providing one or more additional paths of heat dissipation between extents (e.g., along the z-direction) of the device 600, by reducing an amount of heat that is dissipated along the z-direction through other dies 302-e (e.g., reducing an amount of heat generated or carried by one die 302-e being carried through another die 302-e), among other examples.

Thus, a first die 302-e may be associated with a first width dimension (e.g., along the x-direction, along the y-direction, in an xy-plane), a second die 302-e may be associated with a second width dimension, and one or more portions of the dielectric material 305-d may be associated with a third width dimension that extends beyond the first width dimension and the second width dimension. To support the described improvements for heat dissipation in a device 600, the extension of coupling components 405-d may be greater than a stacking tolerance (e.g., along the x-direction, along the y-direction, in an xy-plane) associated with stacking coupling components and dies 302-e. For example, a coupling component 405-d may extend beyond both sides of one or more dies 302-e (e.g., adjacent dies 302-e) along the x-direction, beyond both sides of one or more dies 302-e along the y-direction, or beyond both sides along both the x-direction and the y-direction. Additionally, or alternatively, a coupling component 405-d may extend beyond one or more dies 302-e, on one or both sides along the x-direction, along the y-direction, or both (e.g., along one or more directions in an xy-plane), by at least a threshold dimension, such as extending beyond one or more dies 302-e by at least 100 microns, by at least 500 microns, or by at least 1 millimeter, by at least 5% of an extent of die(s) 302-e, by at least 10% of die(s) 302-e, among other dimensions of extension, which may be configured based on a balance between a desired heat transfer performance of a device 600 and packaging constraints for a device 600, among other considerations.

In some examples, a fabrication operation of the device 600 may include forming, after bonding a coupling component 405-d with a first die 302-e (e.g., a first semiconductor component) and a second die 302-e (e.g., a second semiconductor component), a coating material 605 (e.g., an outer coating of a HTCD material, an outer coating of a metal material) around the components of the device 600. In some examples, the coating material 605 may have a thermal conductivity that is greater than the thermal conductivity of dielectric materials of the dies 302-e (e.g., and may have a same thermal conductivity of the dielectric material 305-d or a different thermal conductivity).

Thus, by implementing one or more techniques herein, a device 600 may be manufactured with an increased ability to dissipate heat based on the oversizing of the coupling components 405-d. That is, the fin portions extending beyond the edges of respective dies 302-e may create additional surface area (e.g., heatsinks) that enable additional heat flow and heat dissipation, resulting in further improvements to thermal performance and provide additional benefits to support relatively larger storage capacities and power densities, among other benefits.

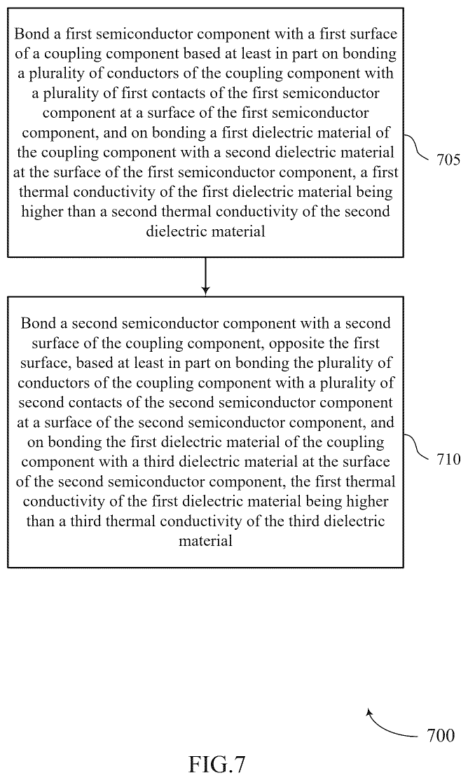

FIG. 7 shows a flowchart illustrating a method or methods 700 that support thermal distribution layers in stacked semiconductor architectures in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 705, the method may include bonding a first semiconductor component with a first surface of a coupling component based at least in part on bonding a plurality of conductors of the coupling component with a plurality of first contacts of the first semiconductor component at a surface of the first semiconductor component, and on bonding a first dielectric material of the coupling component with a second dielectric material at the surface of the first semiconductor component, a first thermal conductivity of the first dielectric material being higher than a second thermal conductivity of the second dielectric material.

At 710, the method may include bonding a second semiconductor component with a second surface of the coupling component, opposite the first surface, based at least in part on bonding the plurality of conductors of the coupling component with a plurality of second contacts of the second semiconductor component at a surface of the second semiconductor component, and on bonding the first dielectric material of the coupling component with a third dielectric material at the surface of the second semiconductor component, the first thermal conductivity of the first dielectric material being higher than a third thermal conductivity of the third dielectric material.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for bonding a first semiconductor component with a first surface of a coupling component based at least in part on bonding a plurality of conductors of the coupling component with a plurality of first contacts of the first semiconductor component at a surface of the first semiconductor component, and on bonding a first dielectric material of the coupling component with a second dielectric material at the surface of the first semiconductor component, a first thermal conductivity of the first dielectric material being higher than a second thermal conductivity of the second dielectric material and bonding a second semiconductor component with a second surface of the coupling component, opposite the first surface, based at least in part on bonding the plurality of conductors of the coupling component with a plurality of second contacts of the second semiconductor component at a surface of the second semiconductor component, and on bonding the first dielectric material of the coupling component with a third dielectric material at the surface of the second semiconductor component, the first thermal conductivity of the first dielectric material being higher than a third thermal conductivity of the third dielectric material.

Aspect 2: The method or apparatus of aspect 1, where the first dielectric material bonded with the second dielectric material is contiguous with the first dielectric material bonded with the third dielectric material.

Aspect 3: The method or apparatus of any of aspects 1 through 2, where circuitry of the first semiconductor component is coupled with circuitry of the second semiconductor component via one or more of the plurality of conductors.

Aspect 4: The method or apparatus of aspect 3, where the circuitry of the first semiconductor component includes a doped portion of a first semiconductor substrate of the first semiconductor component and the circuitry of the second semiconductor component includes a doped portion of a second semiconductor substrate of the second semiconductor component.

Aspect 5: The method or apparatus of any of aspects 3 through 4, where the circuitry of the first semiconductor component includes circuitry associated with accessing a first memory array of the first semiconductor component and the circuitry of the second semiconductor component includes circuitry associated with accessing a second memory array of the second semiconductor component.

Aspect 6: The method or apparatus of any of aspects 1 through 5, further including operations, features, circuitry, logic, means, or instructions, or any combination thereof for forming the coupling component before bonding the coupling component with the first semiconductor component and the second semiconductor component, where forming the coupling component includes; forming the first dielectric material; forming a plurality of cavities into the first surface of the first dielectric material; and forming the plurality of conductors based at least in part on forming a conductive material in the plurality of cavities.

Aspect 7: The method or apparatus of aspect 6, where forming the coupling component further includes operations, features, circuitry, logic, means, or instructions, or any combination thereof for removing a portion of the first dielectric material to expose the plurality of conductors at the second surface of the coupling component.

Aspect 8: The method or apparatus of any of aspects 6 through 7, where forming the coupling component further includes operations, features, circuitry, logic, means, or instructions, or any combination thereof for forming a wafer including a plurality of dielectric materials including the first dielectric material and separating a plurality of coupling components including the coupling component from the wafer.

Aspect 9: The method or apparatus of any of aspects 1 through 8, further including operations, features, circuitry, logic, means, or instructions, or any combination thereof for bonding the second semiconductor component with a first surface of a second coupling component based at least in part on bonding a plurality of second conductors of the second coupling component with a plurality of third contacts of the second semiconductor component at a second surface of the second semiconductor component opposite the surface of the second semiconductor component, and on bonding the first dielectric material of the second coupling component with a fourth dielectric material at the second surface of the second semiconductor component, the first thermal conductivity of the first dielectric material being higher than a fourth thermal conductivity of the fourth dielectric material and bonding a third semiconductor component with a second surface of the second coupling component, opposite the first surface of the second coupling component, based at least in part on bonding the plurality of second conductors of the second coupling component with a plurality of fourth contacts of the third semiconductor component at a surface of the third semiconductor component, and on bonding the first dielectric material of the second coupling component with a fifth dielectric material at the surface of the third semiconductor component, the first thermal conductivity of the first dielectric material being higher than a fifth thermal conductivity of the fifth dielectric material.

Aspect 10: The method or apparatus of any of aspects 1 through 9, further including operations, features, circuitry, logic, means, or instructions, or any combination thereof for forming, after bonding the coupling component with the first semiconductor component and the second semiconductor component, a coating material around the first semiconductor component, the second semiconductor component, and the coupling component, the coating material having a thermal conductivity greater than the second thermal conductivity and the third thermal conductivity.

Aspect 11: The method or apparatus of any of aspects 1 through 10, where the first dielectric material includes aluminum nitride, silicon carbide, silicon nitride, or boron arsenide and the second dielectric material and the third dielectric material include silicon oxide.

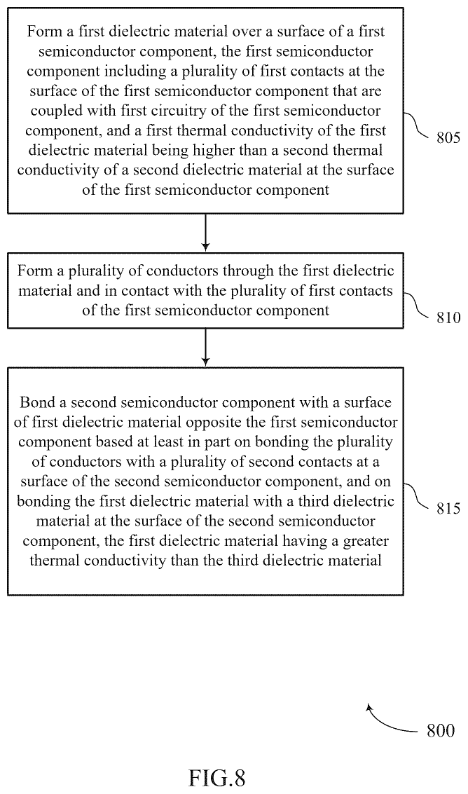

FIG. 8 shows a flowchart illustrating a method or methods 800 that support thermal distribution layers in stacked semiconductor architectures in accordance with examples as disclosed herein. The operations of method 800 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 805, the method may include forming a first dielectric material over a surface of a first semiconductor component, the first semiconductor component including a plurality of first contacts at the surface of the first semiconductor component that are coupled with first circuitry of the first semiconductor component, and a first thermal conductivity of the first dielectric material being higher than a second thermal conductivity of a second dielectric material at the surface of the first semiconductor component.

At 810, the method may include forming a plurality of conductors through the first dielectric material and in contact with the plurality of first contacts of the first semiconductor component.

At 815, the method may include bonding a second semiconductor component with a surface of first dielectric material opposite the first semiconductor component based at least in part on bonding the plurality of conductors with a plurality of second contacts at a surface of the second semiconductor component, and on bonding the first dielectric material with a third dielectric material at the surface of the second semiconductor component, the first dielectric material having a greater thermal conductivity than the third dielectric material.

In some examples, an apparatus (e.g., a manufacturing system) as described herein may perform a method or methods, such as the method 800. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 12: A method or apparatus including operations, features, circuitry, logic, means, or instructions, or any combination thereof for forming a first dielectric material over a surface of a first semiconductor component, the first semiconductor component including a plurality of first contacts at the surface of the first semiconductor component that are coupled with first circuitry of the first semiconductor component, and a first thermal conductivity of the first dielectric material being higher than a second thermal conductivity of a second dielectric material at the surface of the first semiconductor component; forming a plurality of conductors through the first dielectric material and in contact with the plurality of first contacts of the first semiconductor component; and bonding a second semiconductor component with a surface of first dielectric material opposite the first semiconductor component based at least in part on bonding the plurality of conductors with a plurality of second contacts at a surface of the second semiconductor component, and on bonding the first dielectric material with a third dielectric material at the surface of the second semiconductor component, the first dielectric material having a greater thermal conductivity than the third dielectric material.

Aspect 13: The method or apparatus of aspect 12, where forming the plurality of conductors includes operations, features, circuitry, logic, means, or instructions, or any combination thereof for forming a plurality of cavities through the first dielectric material, each cavity exposing a respective first contact of the plurality of first contacts and forming a conductive material in the plurality of cavities.

Aspect 14: The method or apparatus of any of aspects 12 through 13, where circuitry of the first semiconductor component is coupled with circuitry of the second semiconductor component via one or more of the plurality of conductors.

Aspect 15: The method or apparatus of any of aspects 12 through 14, where forming the first dielectric material includes operations, features, circuitry, logic, means, or instructions, or any combination thereof for forming a first thickness of the first dielectric material associated with respective first portions of the plurality of conductors and forming, after forming the first thickness and the respective first portions of the plurality of conductors, a second thickness of the first dielectric material over the first thickness, the second thickness associated with respective second portions of the plurality of conductors in contact with the respective first portions.

Aspect 16: The method or apparatus of any of aspects 12 through 15, where the first dielectric material includes aluminum nitride, silicon carbide, silicon nitride, or boron arsenide and the second dielectric material and the third dielectric material include silicon oxide.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 17: A semiconductor system, including: a first semiconductor die including first circuitry, a surface of the first semiconductor die including a first dielectric material; a second semiconductor die including second circuitry, a surface of the second semiconductor die including a second dielectric material; a third dielectric material between the first semiconductor die and the second semiconductor die, a first surface of the third dielectric material being in contact with the surface of the first semiconductor die, a second surface of the third dielectric material opposite the first surface being in contact with the surface of the second semiconductor die, and the third dielectric material having a higher thermal conductivity than the first dielectric material and the second dielectric material; and a plurality of conductors through the third dielectric material and coupling the first circuitry of the first semiconductor die with the second circuitry of the second semiconductor die.

Aspect 18: The semiconductor system of aspect 17, further including: a first plurality of contacts of the first semiconductor die that are respectively coupled with the plurality of conductors at the surface of the first semiconductor die; and a second plurality of contacts of the second semiconductor die that are respectively coupled with the plurality of conductors at the surface of the second semiconductor die, where the first circuitry is coupled with the second circuitry via the first plurality of contacts and the second plurality of contacts.

Aspect 19: The semiconductor system of any of aspects 17 through 18, where: the first semiconductor die is associated with a first width dimension; the second semiconductor die is associated with a second width dimension; and the third dielectric material is associated with a third width dimension that extends beyond the first width dimension and the second width dimension.

Aspect 20: The semiconductor system of aspect 19, further including: a coating material formed around the first semiconductor die, the second semiconductor die, and the third dielectric material.

Aspect 21: The semiconductor system of any of aspects 17 through 20, where: the first dielectric material and the second dielectric material include silicon oxide; and the third dielectric material includes aluminum nitride, silicon carbide, silicon nitride, or boron arsenide.

Aspect 22: The semiconductor system of any of aspects 17 through 21, further including: a second portion of the third dielectric material in contact with a second surface of the first semiconductor die opposite the surface of the first semiconductor die; and a third portion of the third dielectric material in contact with a second surface of the second semiconductor die opposite the surface of the second semiconductor die.

Aspect 23: The semiconductor system of any of aspects 17 through 22, where a first end of at least one conductor of the plurality of conductors has a larger width than a second end of the at least one conductor.

Aspect 24: The semiconductor system of any of aspects 17 through 23, further including: a plurality of solder contacts at a second surface of the second semiconductor die opposite the surface of the second semiconductor die.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor system, comprising:
a first semiconductor die comprising first circuitry, a surface of the first semiconductor die comprising a first dielectric material;
a second semiconductor die comprising second circuitry, a surface of the second semiconductor die comprising a second dielectric material;
a third dielectric material between the first semiconductor die and the second semiconductor die, a first surface of the third dielectric material being in contact with the surface of the first semiconductor die, a second surface of the third dielectric material opposite the first surface being in contact with the surface of the second semiconductor die, and the third dielectric material having a higher thermal conductivity than the first dielectric material and the second dielectric material; and
a plurality of conductors through the third dielectric material and coupling the first circuitry of the first semiconductor die with the second circuitry of the second semiconductor die.

2. The semiconductor system of claim 1, further comprising:
a first plurality of contacts of the first semiconductor die that are respectively coupled with the plurality of conductors at the surface of the first semiconductor die; and
a second plurality of contacts of the second semiconductor die that are respectively coupled with the plurality of conductors at the surface of the second semiconductor die, wherein the first circuitry is coupled with the second circuitry via the first plurality of contacts and the second plurality of contacts.

3. The semiconductor system of claim 1, wherein:
the first semiconductor die is associated with a first width dimension;
the second semiconductor die is associated with a second width dimension; and
the third dielectric material is associated with a third width dimension that extends beyond the first width dimension and the second width dimension.

4. The semiconductor system of claim 3, further comprising:
a coating material formed around the first semiconductor die, the second semiconductor die, and the third dielectric material.

5. The semiconductor system of claim 1, wherein:
the first dielectric material and the second dielectric material comprise silicon oxide; and
the third dielectric material comprises aluminum nitride, silicon carbide, silicon nitride, or boron arsenide.

6. The semiconductor system of claim 1, further comprising:
a second portion of the third dielectric material in contact with a second surface of the first semiconductor die opposite the surface of the first semiconductor die; and
a third portion of the third dielectric material in contact with a second surface of the second semiconductor die opposite the surface of the second semiconductor die.

7. The semiconductor system of claim 1, wherein a first end of at least one conductor of the plurality of conductors has a larger width than a second end of the at least one conductor.

8. The semiconductor system of claim 1, further comprising:
a plurality of solder contacts at a second surface of the second semiconductor die opposite the surface of the second semiconductor die.

9. A method for manufacturing a semiconductor system, comprising:
bonding a first semiconductor component with a first surface of a coupling component based at least in part on bonding a plurality of conductors of the coupling component with a plurality of first contacts of the first semiconductor component at a surface of the first semiconductor component, and on bonding a first dielectric material of the coupling component with a second dielectric material at the surface of the first semiconductor component, a first thermal conductivity of the first dielectric material being higher than a second thermal conductivity of the second dielectric material; and
bonding a second semiconductor component with a second surface of the coupling component, opposite the first surface, based at least in part on bonding the plurality of conductors of the coupling component with a plurality of second contacts of the second semiconductor component at a surface of the second semiconductor component, and on bonding the first dielectric material of the coupling component with a third dielectric material at the surface of the second semiconductor component, the first thermal conductivity of the first dielectric material being higher than a third thermal conductivity of the third dielectric material.

10. The method of claim 9, wherein the first dielectric material bonded with the second dielectric material is contiguous with the first dielectric material bonded with the third dielectric material.

11. The method of claim 9, wherein circuitry of the first semiconductor component is coupled with circuitry of the second semiconductor component via one or more of the plurality of conductors.

12. The method of claim 11, wherein:
the circuitry of the first semiconductor component comprises a doped portion of a first semiconductor substrate of the first semiconductor component; and
the circuitry of the second semiconductor component comprises a doped portion of a second semiconductor substrate of the second semiconductor component.

13. The method of claim 11, wherein:
the circuitry of the first semiconductor component comprises circuitry associated with accessing a first memory array of the first semiconductor component; and
the circuitry of the second semiconductor component comprises circuitry associated with accessing a second memory array of the second semiconductor component.

14. The method of claim 9, further comprising:
forming the coupling component before bonding the coupling component with the first semiconductor component and the second semiconductor component, wherein forming the coupling component comprises:
forming the first dielectric material;
forming a plurality of cavities into the first surface of the first dielectric material; and
forming the plurality of conductors based at least in part on forming a conductive material in the plurality of cavities.

15. The method of claim 14, wherein forming the coupling component further comprises:
removing a portion of the first dielectric material to expose the plurality of conductors at the second surface of the coupling component.

16. The method of claim 14, wherein forming the coupling component further comprises:
forming a wafer comprising a plurality of dielectric materials including the first dielectric material; and
separating a plurality of coupling components including the coupling component from the wafer.

17. The method of claim 9, further comprising:
bonding the second semiconductor component with a first surface of a second coupling component based at least in part on bonding a plurality of second conductors of the second coupling component with a plurality of third contacts of the second semiconductor component at a second surface of the second semiconductor component opposite the surface of the second semiconductor component, and on bonding the first dielectric material of the second coupling component with a fourth dielectric material at the second surface of the second semiconductor component, the first thermal conductivity of the first dielectric material being higher than a fourth thermal conductivity of the fourth dielectric material; and
bonding a third semiconductor component with a second surface of the second coupling component, opposite the first surface of the second coupling component, based at least in part on bonding the plurality of second conductors of the second coupling component with a plurality of fourth contacts of the third semiconductor component at a surface of the third semiconductor component, and on bonding the first dielectric material of the second coupling component with a fifth dielectric material at the surface of the third semiconductor component, the first thermal conductivity of the first dielectric material being higher than a fifth thermal conductivity of the fifth dielectric material.

18. The method of claim 9, further comprising:
forming, after bonding the coupling component with the first semiconductor component and the second semiconductor component, a coating material around the first semiconductor component, the second semiconductor component, and the coupling component, the coating material having a thermal conductivity greater than the second thermal conductivity and the third thermal conductivity.

19. The method of claim 9, wherein:
the first dielectric material comprises aluminum nitride, silicon carbide, silicon nitride, or boron arsenide; and
the second dielectric material and the third dielectric material comprise silicon oxide.

20. A method for semiconductor device manufacture, comprising:
forming a first dielectric material over a surface of a first semiconductor component, the first semiconductor component comprising a plurality of first contacts at the surface of the first semiconductor component that are coupled with first circuitry of the first semiconductor component, and a first thermal conductivity of the first dielectric material being higher than a second thermal conductivity of a second dielectric material at the surface of the first semiconductor component;
forming a plurality of conductors through the first dielectric material and in contact with the plurality of first contacts of the first semiconductor component; and
bonding a second semiconductor component with a surface of first dielectric material opposite the first semiconductor component based at least in part on bonding the plurality of conductors with a plurality of second contacts at a surface of the second semiconductor component, and on bonding the first dielectric material with a third dielectric material at the surface of the second semiconductor component, the first dielectric material having a greater thermal conductivity than the third dielectric material.

21. The method of claim 20, wherein forming the plurality of conductors comprises:
forming a plurality of cavities through the first dielectric material, each cavity exposing a respective first contact of the plurality of first contacts; and
forming a conductive material in the plurality of cavities.

22. The method of claim 20, wherein circuitry of the first semiconductor component is coupled with circuitry of the second semiconductor component via one or more of the plurality of conductors.

23. The method of claim 20, wherein forming the first dielectric material comprises:
forming a first thickness of the first dielectric material associated with respective first portions of the plurality of conductors; and
forming, after forming the first thickness and the respective first portions of the plurality of conductors, a second thickness of the first dielectric material over the first thickness, the second thickness associated with respective second portions of the plurality of conductors in contact with the respective first portions.

24. The method of claim 20, wherein:
the first dielectric material comprises aluminum nitride, silicon carbide, silicon nitride, or boron arsenide; and
the second dielectric material and the third dielectric material comprise silicon oxide.
